(19) United States
(12) Patent Application Publication
(10) Pub. No.: US 2025/0330143 A1
(43) Pub. Date: Oct. 23, 2025

(54) SURFACE ACOUSTIC WAVE DEVICE WITH INTERDIGITAL TRANSDUCER ELECTRODE FINGERS HAVING MULTIPLE LINER DENSITIES IN BORDER REGION

(71) Applicant: Skyworks Solutions, Inc., Irvine, CA (US)

(72) Inventors: Rei Goto, Osaka-Shi (JP); Mitsuhiro Habuta, Osaka-Shi (JP)

(21) Appl. No.: 19/173,122

(22) Filed: Apr. 8, 2025

Related U.S. Application Data
(60) Provisional application No. 63/637,498, filed on Apr. 23, 2024.
(60) Provisional application No. 63/637,489, filed on Apr. 23, 2024.
(60) Provisional application No. 63/637,505, filed on Apr. 23, 2024.
(60) Provisional application No. 63/637,506, filed on Apr. 23, 2024.

(51) Int. Cl. H03H 9/145; H03H 3/08; H03H 9/02

(52) U.S. Cl. CPC H03H 9/14547; H03H 3/08; H03H 9/02992; H03H 9/14541

(57) ABSTRACT

A multilayer piezoelectric substrate acoustic wave device including an active region having a center region and a border region is disclosed. The acoustic wave device can include a support substrate, a piezoelectric layer over the support substrate, and an interdigital transducer electrode in electrical communication with the piezoelectric layer. The interdigital transducer electrode includes a bus bar and a finger extending from the bus bar. The finger in the border region has a first portion, a second portion between the center region and the first portion, and a third portion between the center region and the second portion. The first portion and the third portion have liner densities greater than liner densities of the second portion and the finger in the center region.

### INCORPORATION BY REFERENCE TO ANY PRIORITY APPLICATIONS

Any and all applications for which a foreign or domestic priority claim is identified in the Application Data Sheet as filed with the present application, including U.S. Provisional Patent Application No. 63/637,498, filed Apr. 23, 2024, titled “SURFACE ACOUSTIC WAVE DEVICE WITH TRANSVERSE MODE SUPPRESSION,” U.S. Provisional Patent Application No. 63/637,489, filed Apr. 23, 2024, titled “PISTON MODE FOR SURFACE ACOUSTIC WAVE DEVICE,” U.S. Provisional Patent Application No. 63/637,505, filed Apr. 23, 2024, titled “MULTILAYER PIEZOELECTRIC SUBSTRATE SURFACE ACOUSTIC WAVE DEVICE WITH TRANSVERSE MODE SUPPRESSION,” and U.S. Provisional Patent Application No. 63/637,506, filed Apr. 23, 2024, titled “SURFACE ACOUSTIC WAVE DEVICE WITH INTERDIGITAL TRANSDUCER ELECTRODE FINGERS HAVING MULTIPLE LINER DENSITIES IN BORDER REGION,” are hereby incorporated by reference under 37 CFR 1.57 in their entirety.

### BACKGROUND

### Field

Embodiments of this disclosure relate to multilayer piezoelectric substrate surface acoustic wave (MPS SAW) devices.

### Description of Related Technology

Acoustic wave filters can be implemented in radio frequency electronic apparatuses. For instance, filters in a radio frequency front end of a mobile phone can include acoustic wave filters. An acoustic wave filter can filter a radio frequency signal. An acoustic wave filter can be a band pass filter. A plurality of acoustic wave filters can be arranged as a multiplexer. For example, two acoustic wave filters can be arranged as a duplexer.

An acoustic wave filter can include a plurality of resonators arranged to filter a radio frequency signal. Example acoustic wave filters include surface acoustic wave (SAW) filters and bulk acoustic wave (BAW) filters. A surface acoustic wave resonator can include an interdigital transductor electrode on a piezoelectric substrate. The surface acoustic wave resonator can generate a surface acoustic wave on a surface of the piezoelectric layer on which the interdigital transductor electrode is disposed.

### SUMMARY

The innovations described in the claims each have several aspects, no single one of which is solely responsible for its desirable attributes. Without limiting the scope of the claims, some prominent features of this disclosure will now be briefly described.

In some aspects, the techniques described herein relate to a multilayer piezoelectric substrate acoustic wave device including an active region having a center region and a border region, the acoustic wave device including: a support substrate; a piezoelectric layer over the support substrate; and an interdigital transducer electrode in electrical communication with the piezoelectric layer, the interdigital transducer electrode including a bus bar and a finger extending from the bus bar, the finger in the border region having a first portion with a first width, a second portion with a second width between the center region and the first portion, and a third portion with a third width between the center region and the second portion, the finger in the center region having a fourth width, the first width and the third width being wider than the second width and the fourth width.

In some embodiments, the techniques described herein relate to an acoustic wave device wherein the interdigital transducer electrode includes a first layer having a first material and a second layer having a second material different from the first material.

In some embodiments, the techniques described herein relate to an acoustic wave device wherein the interdigital transducer electrode includes a mini-bus bar between the bus bar and the active region.

In some embodiments, the techniques described herein relate to an acoustic wave device wherein the first width of the first portion is at least 5% greater than the second width of the second portion.

In some embodiments, the techniques described herein relate to an acoustic wave device wherein the first width of the first portion is 5% to 50% greater than the second width of the second portion.

In some embodiments, the techniques described herein relate to an acoustic wave device wherein the first width of the first portion is 15% to 40% greater than the second width of the second portion.

In some embodiments, the techniques described herein relate to an acoustic wave device wherein the first width of the first portion and the third width of the third portion are different.

In some embodiments, the techniques described herein relate to an acoustic wave device wherein the border region is a region within 1.5L from an edge of the finger farthest from the bus bar, where a surface acoustic wave generated by the acoustic wave device has a wavelength L.

In some embodiments, the techniques described herein relate to an acoustic wave device wherein the second portion has a length that extends between the first portion and the third portion in a range of 0.1L and 0.7L.

In some embodiments, the techniques described herein relate to an acoustic wave device wherein the fourth width of the finger in the center region is greater than a fifth width of the finger in a gap region between the active region and the bus bar.

In some aspects, the techniques described herein relate to a method of forming a multilayer piezoelectric substrate acoustic wave device including an active region having a center region and a border region, the method including: providing a support substrate; providing a piezoelectric layer over the support substrate; and providing an interdigital transducer electrode in electrical communication with the piezoelectric layer, the interdigital transducer electrode including a bus bar and a finger extending from the bus bar, the finger in the border region having a first portion with a first width, a second portion with a second width between the center region and the first portion, and a third portion with a third width between the center region and the second portion, the finger in the center region having a fourth width, the first width and the third width being wider than the second width and the fourth width.

In some embodiments, the techniques described herein relate to a method wherein the interdigital transducer electrode includes a first layer having a first material and a second layer having a second material different from the first material.

In some embodiments, the techniques described herein relate to a method wherein providing the interdigital transducer electrode includes forming a mini-bus bar between the bus bar and the active region.

In some embodiments, the techniques described herein relate to a method wherein the first width of the first portion is at least 5% greater than the second width of the second portion.

In some embodiments, the techniques described herein relate to a method wherein the first width of the first portion is 5% to 50% greater than the second width of the second portion.

In some embodiments, the techniques described herein relate to a method wherein the first width of the first portion is 15% to 40% greater than the second width of the second portion.

In some embodiments, the techniques described herein relate to a method wherein the first width of the first portion and the third width of the third portion are different.

In some embodiments, the techniques described herein relate to a method wherein the border region is a region within 1.5L from an edge of the finger farthest from the bus bar, where a surface acoustic wave generated by the acoustic wave device has a wavelength L.

In some embodiments, the techniques described herein relate to a method wherein the second portion has a length that extends between the first portion and the third portion in a range of 0.1L and 0.7L.

In some embodiments, the techniques described herein relate to a method wherein the fourth width of the finger in the center region is greater than a fifth width of the finger in a gap region between the active region and the bus bar.

In some aspects, the techniques described herein relate to a multilayer piezoelectric substrate acoustic wave device including an active region having a center region and a border region, the acoustic wave device including: a support substrate; a piezoelectric layer over the support substrate; and an interdigital transducer electrode in electrical communication with the piezoelectric layer, the interdigital transducer electrode including a bus bar and a finger extending from the bus bar, the finger in the border region having a first portion, a second portion, and a third portion, the second portion positioned between the first portion and the third portion, the first portion and the third portion being wider than the second portion and the finger in the center region.

In some aspects, the techniques described herein relate to a multilayer piezoelectric substrate acoustic wave device including an active region having a center region and a border region, the acoustic wave device including: a support substrate; a piezoelectric layer over the support substrate; and an interdigital transducer electrode in electrical communication with the piezoelectric layer, the interdigital transducer electrode including a bus bar and a finger extending from the bus bar, the finger in the border region having a first portion with a first thickness, a second portion with a second thickness between the center region and the first portion, and a third portion with a third thickness between the center region and the second portion, the finger in the center region having a fourth thickness, the first thickness and the third thickness being thicker than the second thickness and the fourth thickness.

In some embodiments, the techniques described herein relate to an acoustic wave device wherein the interdigital transducer electrode includes a first layer having a first material and a second layer having a second material different from the first material.

In some embodiments, the techniques described herein relate to an acoustic wave device wherein the interdigital transducer electrode includes a mini-bus bar between the bus bar and the active region.

In some embodiments, the techniques described herein relate to an acoustic wave device wherein the first thickness of the first portion is at least 5% greater than the second thickness of the second portion.

In some embodiments, the techniques described herein relate to an acoustic wave device wherein the first thickness of the first portion is 5% to 50% greater than the second thickness of the second portion.

In some embodiments, the techniques described herein relate to an acoustic wave device wherein the first thickness of the first portion is 15% to 40% greater than the second thickness of the second portion.

In some embodiments, the techniques described herein relate to an acoustic wave device wherein the first thickness of the first portion and the third thickness of the third portion are different.

In some embodiments, the techniques described herein relate to an acoustic wave device wherein the border region is a region within 1.5L from an edge of the finger farthest from the bus bar, where a surface acoustic wave generated by the acoustic wave device has a wavelength L.

In some embodiments, the techniques described herein relate to an acoustic wave device wherein the second portion has a length that extends between the first portion and the third portion in a range of 0.1L and 0.7L.

In some embodiments, the techniques described herein relate to an acoustic wave device wherein the fourth thickness of the finger in the center region is greater than a fifth thickness of the finger in a gap region between the active region and the bus bar.

In some aspects, the techniques described herein relate to a method of forming a multilayer piezoelectric substrate acoustic wave device including an active region having a center region and a border region, the method including: providing a support substrate; providing a piezoelectric layer over the support substrate; and providing an interdigital transducer electrode in electrical communication with the piezoelectric layer, the interdigital transducer electrode including a bus bar and a finger extending from the bus bar, the finger in the border region having a first portion with a first thickness, a second portion with a second thickness between the center region and the first portion, and a third portion with a third thickness between the center region and the second portion, the finger in the center region having a fourth thickness, the first thickness and the third thickness being thicker than the second thickness and the fourth thickness.

In some embodiments, the techniques described herein relate to a method wherein the interdigital transducer electrode includes a first layer having a first material and a second layer having a second material different from the first material.

In some embodiments, the techniques described herein relate to a method wherein providing the interdigital transducer electrode includes forming a mini-bus bar between the bus bar and the active region.

In some embodiments, the techniques described herein relate to a method wherein the first thickness of the first portion is at least 5% greater than the second thickness of the second portion.

In some embodiments, the techniques described herein relate to a method wherein the first thickness of the first portion is 5% to 50% greater than the second thickness of the second portion.

In some embodiments, the techniques described herein relate to a method wherein the first thickness of the first portion is 15% to 40% greater than the second thickness of the second portion.

In some embodiments, the techniques described herein relate to a method wherein the first thickness of the first portion and the third thickness of the third portion are different.

In some embodiments, the techniques described herein relate to a method wherein the border region is a region within 1.5L from an edge of the finger farthest from the bus bar, where a surface acoustic wave generated by the acoustic wave device has a wavelength L.

In some embodiments, the techniques described herein relate to an acoustic wave device wherein the second portion has a length that extends between the first portion and the third portion in a range of 0.1L and 0.7L.

In some embodiments, the techniques described herein relate to an acoustic wave device wherein the fourth thickness of the finger in the center region is greater than a fifth thickness of the finger in a gap region between the active region and the bus bar.

In some aspects, the techniques described herein relate to a multilayer piezoelectric substrate acoustic wave device including an active region having a center region and a border region, the acoustic wave device including: a support substrate; a piezoelectric layer over the support substrate; and an interdigital transducer electrode in electrical communication with the piezoelectric layer, the interdigital transducer electrode including a bus bar and a finger extending from the bus bar, the finger in the border region having a first portion, a second portion, and a third portion, the second portion positioned between the first portion and the third portion, the first portion and the third portion being thicker than the second portion and the finger in the center region.

In some aspects, the techniques described herein relate to a multilayer piezoelectric substrate acoustic wave device including an active region having a center region and a border region, the acoustic wave device including: a support substrate; a piezoelectric layer over the support substrate, the piezoelectric layer having a trench in the border region; and an interdigital transducer electrode in electrical communication with the piezoelectric layer, the interdigital transducer electrode including a bus bar and a finger extending from the bus bar, the finger in the border region having a first portion with a first width, a second portion with a second width between the center region and the first portion, and a third portion with a third width between the center region and the second portion, the second width being narrower than the first width and the third width.

In some embodiments, the techniques described herein relate to an acoustic wave device wherein the interdigital transducer electrode includes a first layer having a first material and a second layer having a second material different from the first material.

In some embodiments, the techniques described herein relate to an acoustic wave device wherein the interdigital transducer electrode includes a mini-bus bar between the bus bar and the active region.

In some embodiments, the techniques described herein relate to an acoustic wave device wherein the first width of the first portion is at least 5% greater than the second width of the second portion.

In some embodiments, the techniques described herein relate to an acoustic wave device wherein the first width of the first portion is 5% to 50% greater than the second width of the second portion.

In some embodiments, the techniques described herein relate to an acoustic wave device wherein the first width of the first portion is 15% to 40% greater than the second width of the second portion.

In some embodiments, the techniques described herein relate to an acoustic wave device wherein the trench has a trench depth, the trench depth is at least 5% a thickness of the piezoelectric layer.

In some embodiments, the techniques described herein relate to an acoustic wave device wherein the trench depth is in a range between 5% and 50% of the thickness of the piezoelectric layer.

In some embodiments, the techniques described herein relate to an acoustic wave device wherein the border region is a region within 1.5L from an edge of the finger farthest from the bus bar, where a surface acoustic wave generated by the acoustic wave device has a wavelength L.

In some embodiments, the techniques described herein relate to an acoustic wave device wherein the second portion has a length that extends between the first portion and the third portion in a range of 0.1L and 0.7L.

In some aspects, the techniques described herein relate to a method of forming a multilayer piezoelectric substrate acoustic wave device including an active region having a center region and a border region, the method including: providing a support substrate; providing a piezoelectric layer over the support substrate, the piezoelectric layer having a trench in the border region; and providing an interdigital transducer electrode in electrical communication with the piezoelectric layer, the interdigital transducer electrode including a bus bar and a finger extending from the bus bar, the finger in the border region having a first portion with a first width, a second portion with a second width between the center region and the first portion, and a third portion with a third width between the center region and the second portion, the second width being narrower than the first width and the third width.

In some embodiments, the techniques described herein relate to a method wherein the interdigital transducer electrode includes a first layer having a first material and a second layer having a second material different from the first material.

In some embodiments, the techniques described herein relate to a method wherein providing the interdigital transducer electrode includes forming a mini-bus bar between the bus bar and the active region.

In some embodiments, the techniques described herein relate to a method wherein the first width of the first portion is at least 5% greater than the second width of the second portion.

In some embodiments, the techniques described herein relate to a method wherein the first width of the first portion is 5% to 50% greater than the second width of the second portion.

In some embodiments, the techniques described herein relate to a method wherein the first width of the first portion is 15% to 40% greater than the second width of the second portion.

In some embodiments, the techniques described herein relate to a method wherein the trench has a trench depth, the trench depth is at least 5% a thickness of the piezoelectric layer.

In some embodiments, the techniques described herein relate to a method wherein the trench depth is in a range between 5% and 50% of the thickness of the piezoelectric layer.

In some embodiments, the techniques described herein relate to a method wherein the border region is a region within 1.5L from an edge of the finger farthest from the bus bar, where a surface acoustic wave generated by the acoustic wave device has a wavelength L.

In some embodiments, the techniques described herein relate to a method wherein the second portion has a length that extends between the first portion and the third portion in a range of 0.1L and 0.7L.

In some aspects, the techniques described herein relate to a multilayer piezoelectric substrate acoustic wave device including an active region having a center region and a border region, the acoustic wave device including: a support substrate; a piezoelectric layer over the support substrate, the piezoelectric layer having a trench in the border region; and an interdigital transducer electrode in electrical communication with the piezoelectric layer, the interdigital transducer electrode including a bus bar and a finger extending from the bus bar, the finger in the border region having a hammer head structure and a narrow portion, the narrow portion being narrower than the finger in the center region.

In some aspects, the techniques described herein relate to a multilayer piezoelectric substrate acoustic wave device including an active region having a center region and a border region, the acoustic wave device including: a support substrate; a piezoelectric layer over the support substrate; and an interdigital transducer electrode in electrical communication with the piezoelectric layer, the interdigital transducer electrode including a bus bar and a finger extending from the bus bar, the finger in the border region having a first portion, a second portion between the center region and the first portion, and a third portion between the center region and the second portion, a liner density of the first portion and a liner density of the third portion being greater than a liner density of the second portion and a liner density of the finger in the center region.

In some embodiments, the techniques described herein relate to an acoustic wave device wherein the interdigital transducer electrode includes a first layer having a first material and a second layer having a second material different from the first material.

In some embodiments, the techniques described herein relate to an acoustic wave device wherein the interdigital transducer electrode includes a mini-bus bar between the bus bar and the active region.

In some embodiments, the techniques described herein relate to an acoustic wave device wherein the liner density of the first portion is at least 10% greater than the liner density of the second portion.

In some embodiments, the techniques described herein relate to an acoustic wave device wherein the liner density of the first portion is 10% to 40% greater than the liner density of the second portion.

In some embodiments, the techniques described herein relate to an acoustic wave device wherein the liner density of the first portion is 10% to 30% greater than the liner density of the second portion.

In some embodiments, the techniques described herein relate to an acoustic wave device wherein the densities of the first portion and the third portion are different.

In some embodiments, the techniques described herein relate to an acoustic wave device wherein the border region is a region within 1.5L from an edge of the finger farthest from the bus bar, where a surface acoustic wave generated by the acoustic wave device has a wavelength L.

In some embodiments, the techniques described herein relate to an acoustic wave device wherein the second portion has a length that extends between the first portion and the third portion in a range of 0.1L and 0.7L.

In some embodiments, the techniques described herein relate to an acoustic wave device wherein a width of the finger in the center region is greater than a fifth width of the finger in a gap region between the active region and the bus bar.

In some aspects, the techniques described herein relate to a method of forming a multilayer piezoelectric substrate acoustic wave device including an active region having a center region and a border region, the method including: providing a support substrate; providing a piezoelectric layer over the support substrate; and providing an interdigital transducer electrode in electrical communication with the piezoelectric layer, the interdigital transducer electrode including a bus bar and a finger extending from the bus bar, the finger in the border region having a first portion, a second portion between the center region and the first portion, and a third portion between the center region and the second portion, the first portion and the third portion having liner densities greater than liner densities of the second portion and the finger in the center region.

In some embodiments, the techniques described herein relate to a method wherein the interdigital transducer electrode includes a first layer having a first material and a second layer having a second material different from the first material.

In some embodiments, the techniques described herein relate to a method wherein providing the interdigital transducer electrode includes forming a mini-bus bar between the bus bar and the active region.

In some embodiments, the techniques described herein relate to a method wherein the liner density of the first portion is at least 10% greater than the liner density of the second portion.

In some embodiments, the techniques described herein relate to a method wherein the liner density of the first portion is 10% to 40% greater than the liner density of the second portion.

In some embodiments, the techniques described herein relate to a method wherein the liner density of the first portion is 10% to 30% greater than the liner density of the second portion.

In some embodiments, the techniques described herein relate to a method wherein the densities of the first portion and the third portion are different.

In some embodiments, the techniques described herein relate to a method wherein the border region is a region within 1.5L from an edge of the finger farthest from the bus bar, where a surface acoustic wave generated by the acoustic wave device has a wavelength L.

In some embodiments, the techniques described herein relate to a method wherein the second portion has a length that extends between the first portion and the third portion in a range of 0.1L and 0.7L.

In some embodiments, the techniques described herein relate to a method wherein a width of the finger in the center region is greater than a fifth width of the finger in a gap region between the active region and the bus bar.

In some aspects, the techniques described herein relate to a multilayer piezoelectric substrate acoustic wave device including an active region having a center region and a border region, the acoustic wave device including: a support substrate; a piezoelectric layer over the support substrate, the piezoelectric layer having a trench in the border region; and an interdigital transducer electrode in electrical communication with the piezoelectric layer, the interdigital transducer electrode including a bus bar and a finger extending from the bus bar, the finger in the border region having a first portion, a second portion between the center region and the first portion, and a third portion between the center region and the second portion, the first portion and the third portion having liner densities greater than liner density of the second portion.

The present disclosure relates to U.S. patent application Ser. No. ______ [Attorney Docket SKYWRKS.1533A1], titled “SURFACE ACOUSTIC WAVE DEVICE WITH TRANSVERSE MODE SUPPRESSION,” U.S. patent application Ser. No. ______ [Attorney Docket SKYWRKS.1533A2], titled “PISTON MODE FOR SURFACE ACOUSTIC WAVE DEVICE,” and U.S. patent application Ser. No. ______ [Attorney Docket SKYWRKS. 1533A3], titled “MULTILAYER PIEZOELECTRIC SUBSTRATE SURFACE ACOUSTIC WAVE DEVICE WITH TRANSVERSE MODE SUPPRESSION,” filed on even date herewith, the entire disclosure of which is hereby incorporated by reference herein.

### BRIEF DESCRIPTION OF THE DRAWINGS

Embodiments of this disclosure will now be described, by way of non-limiting example, with reference to the accompanying drawings.

FIG. 1A is a schematic top plan view of a surface acoustic wave (SAW) device according to an embodiment.

FIG. 1B is a schematic cross sectional side view of the SAW device of FIG. 1A.

FIG. 1C is a schematic top plan view of a portion of the SAW device of FIG. 1A.

FIG. 1D is a schematic top plan view of a portion of a SAW device that has a single hammer head structure.

FIGS. 2A-2C are graphs showing simulation results of the SAW devices of FIGS. 1C and 1D.

FIG. 3A is a schematic top plan view of the SAW device of a SAW device according to an embodiment.

FIG. 3B is a schematic cross-sectional side view of the SAW device of FIG. 3A taken along a section of the SAW device.

FIG. 3C is a schematic cross-sectional side view of the SAW device of FIG. 3A taken along another section of the SAW device.

FIG. 3D is a schematic top plan view of a portion of the SAW device of FIGS. 3A-3C.

FIGS. 4A-4C are graphs showing simulation results of the SAW device.

FIG. 5A is a schematic top plan view of a SAW device according to an embodiment.

FIG. 5B is a schematic cross-sectional side view of the SAW device of FIG. 5A.

FIG. 5C is a schematic cross-sectional side view of a portion of the SAW device of FIG. 5A.

FIG. 6A is a schematic diagram of a transmit filter that includes a surface acoustic wave resonator according to an embodiment.

FIG. 6B is a schematic diagram of a receive filter that includes a surface acoustic wave resonator according to an embodiment.

FIG. 7 is a schematic diagram of a radio frequency module that includes a surface acoustic wave resonator according to an embodiment.

FIG. 8 is a schematic diagram of a radio frequency module that includes filters with surface acoustic wave resonators according to an embodiment.

FIG. 9 is a schematic block diagram of a module that includes an antenna switch and duplexers that include a surface acoustic wave resonator according to an embodiment.

FIG. 10A is a schematic block diagram of a module that includes a power amplifier, a radio frequency switch, and duplexers that include a surface acoustic wave resonator according to an embodiment.

FIG. 10B is a schematic block diagram of a module that includes filters, a radio frequency switch, and a low noise amplifier according to an embodiment.

FIG. 11A is a schematic block diagram of a wireless communication device that includes a filter with a surface acoustic wave resonator in accordance with one or more embodiments.

FIG. 11B is a schematic block diagram of another wireless communication device that includes a filter with a surface acoustic wave resonator in accordance with one or more embodiments.

### DETAILED DESCRIPTION

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Acoustic wave filters can filter radio frequency (RF) signals in a variety of applications, such as in an RF front end of a mobile phone. An acoustic wave filter can be implemented with surface acoustic wave (SAW) devices. SAW devices include SAW resonators, SAW delay lines, and multi-mode SAW (MMS) filters (e.g., double mode SAW (DMS) filters). Certain SAW devices may be referred to as SAW resonators. Various features discussed herein can be implemented in any suitable SAW device such as a temperature compensated (TC) SAW device and a multilayer piezoelectric substrate (MPS) SAW device.

In general, high quality factor (Q), large effective electromechanical coupling coefficient (k²_{eff}), high frequency ability, and spurious free can be significant aspects for micro resonators to enable low-loss filters, stable oscillators, and sensitive sensors. SAW resonators can have a relatively strong transverse mode in and/or near a pass band. The presence of the relatively strong transverse modes can hinder the accuracy and/or stability of oscillators and sensors, as well as hurt the performance of acoustic filters by creating relatively severe passband ripples and possibly limiting the rejection.

Therefore, transverse mode suppression is significant for SAW resonators. A technical solution for suppressing transverse modes is to create a border region with a different velocity from a central part of the active region according to the mode dispersion characteristic. This can be referred to as a “piston mode.” A piston mode can be obtained to reduce or cancel out the transverse wave vector in a lateral direction.

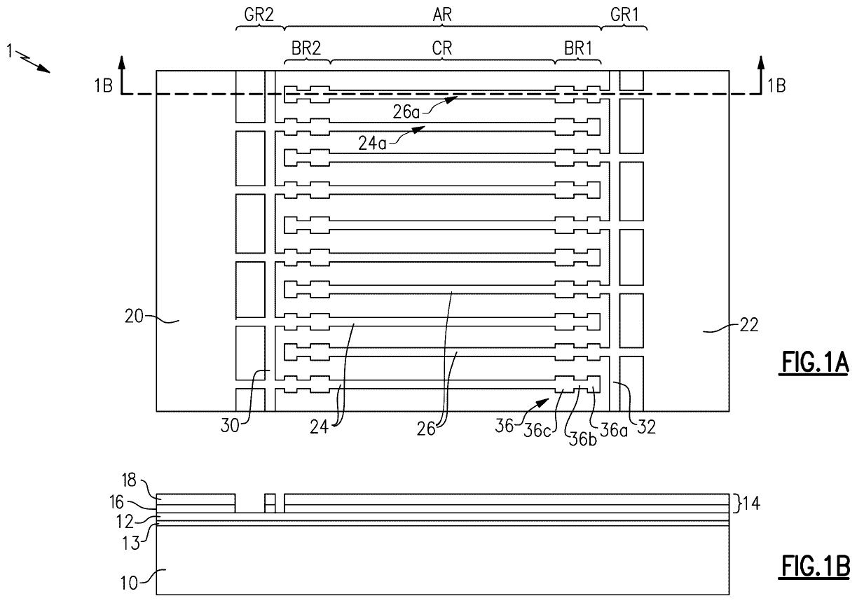

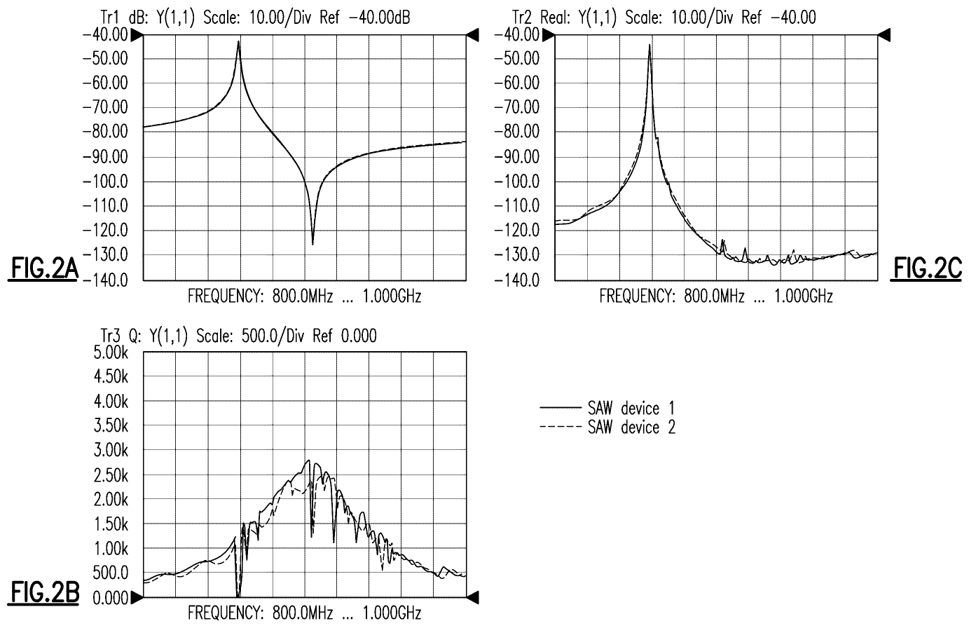

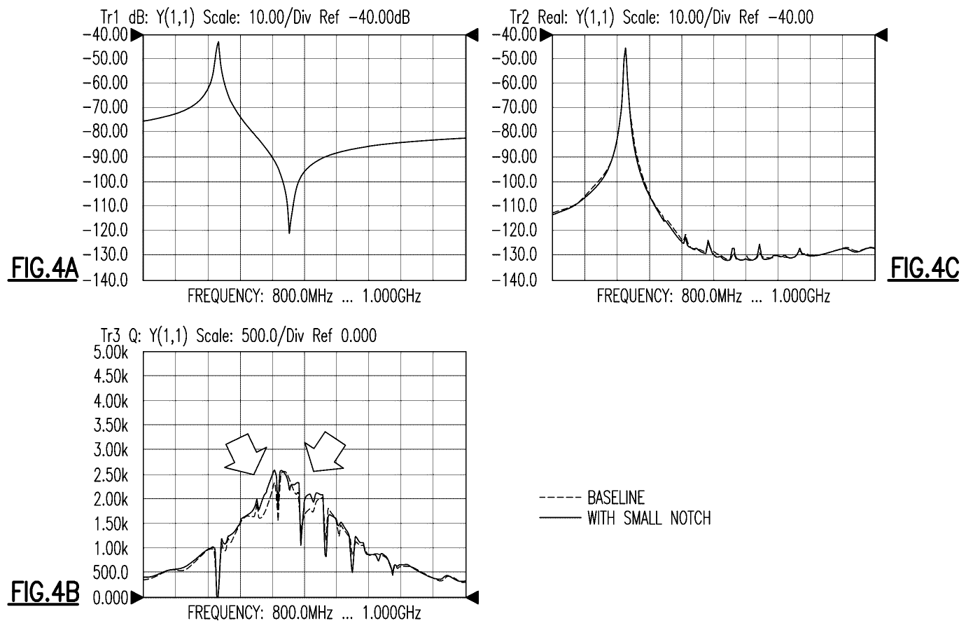

Various embodiments disclosed herein relate to transverse mode suppression structures (e.g., piston mode structures) in a surface acoustic wave (SAW) device (e.g., a multilayer piezoelectric substrate surface acoustic wave (MPS-SAW) device) that can suppress the transverse mode without significantly degrading the k² or Q. In some embodiments, the SAW device can include a multi-hammer head structure (e.g., a double-hammer head structure) (see FIGS. 1A-1C), a notch in a border region (see FIGS. 3A-3D), a trench in the border region (see FIGS. 3A-3D), and/or a multi-thickness step structure (see FIGS. 5A-5C).

FIG. 1A is a schematic top plan view of a surface acoustic wave (SAW) device 1 according to an embodiment. FIG. 1B is a schematic cross-sectional side view of the SAW device 1 of FIG. 1A. FIG. 1C is a schematic top plan view of a portion of the SAW device 1 of FIG. 1A. The surface acoustic wave device 1 is an example of a multilayer piezoelectric substrate surface acoustic wave MPS-SAW device. The SAW device 1 can include a support substrate 10, a piezoelectric layer 12, an intermediate layer 13 between the support substrate 10 and the piezoelectric layer 12, and an interdigital transducer (IDT) electrode 14 in electrical communication with the piezoelectric layer. In the illustrated embodiment, the IDT electrode 14 is formed over the piezoelectric layer 12. The principles and advantages disclosed herein may be implemented in any SAW device, such as a temperature compensated surface acoustic wave (TC-SAW) device that includes a temperature compensation layer over the IDT electrode 14.

The support substrate 10 can be any suitable substrate layer, such as a silicon layer, a quartz layer, a ceramic layer, a glass layer, a spinel layer, a magnesium oxide spinel layer, a sapphire layer, a diamond layer, a silicon carbide layer, a silicon nitride layer, an aluminum nitride layer, or the like. The support substrate 10 can have a relatively high acoustic impedance. An acoustic impedance of the support substrate 10 can be higher than an acoustic impedance of the piezoelectric layer 12. For instance, the support substrate 10 can have a higher acoustic impedance than an acoustic impedance of lithium niobate and a higher acoustic impedance than lithium tantalate. The acoustic impedance of the support substrate 10 can be higher than an acoustic impedance of silicon dioxide (SiO₂). The SAW resonator 1 including the piezoelectric layer 12 on a support substrate 10 with relatively high thermal conductivity, such as silicon substrate, can achieve better thermal dissipation compared to a similar SAW resonator without the high impedance support substrate 10.

The piezoelectric layer 12 can include any suitable piezoelectric layer, such as a lithium based piezoelectric layer. In some embodiments, the piezoelectric layer 12 can be a lithium tantalate (LT) layer. For example, the piezoelectric layer 12 can be an LT layer having a cut angle of 20° (20° Y-cut X-propagation LT) or a cut angle of 60° (60° Y-cut X-propagation LT). For example, the piezoelectric layer 12 can be 20±10° Y-cut LT, 42±25° Y-cut LT, 42±20° Y-cut LT, 42±15° Y-cut LT, 42±10° Y-cut LT, 42±5° Y-cut LT, 60±20° Y-cut LT, 60±15° Y-cut LT, 60±10° Y-cut LT, or 60±5° Y-cut LT. Any other suitable piezoelectric material, such as a lithium niobate (LN) layer, can be used as the piezoelectric layer 12. For example, the piezoelectric layer 12 can be an LN layer having a cut angle of about 118° (118° Y-cut X-propagation LN) or more or a cut angle of about 132° (132Y-cut X-propagation LN) or less. For example, the piezoelectric layer 12 can be 125±20° Y-cut LN, 125±15° Y-cut LN, 125±10° Y-cut LN, or 125±5° Y-cut LN. A thickness of the piezoelectric layer 12 can be selected based on a wavelength 2 or L of a surface acoustic wave generated by the SAW device 1 in certain applications. In some embodiments, the wavelength L can be in a range between, for example, 3 micrometers and 6 micrometers, 3.5 micrometers and 6 micrometers, 3 micrometers and 5.5 micrometers, or 3.5 micrometers and 5.5 micrometers. The piezoelectric layer 12 can be sufficiently thick to avoid significant frequency variation. For example, the thickness of the piezoelectric layer 12 can be in a range of 0.1L to 0.5, 0.1L to 0.3L, or 0.1L to 0.2L. Selecting the thickness of the piezoelectric layer 12 from these ranges can be critical in avoiding significant frequency variation and providing sufficient temperature coefficient of frequency for the SAW device 1. In some embodiments, the piezoelectric layer 12 can include lithium tantalate (LT) and lithium niobate (LN).

In some embodiments, the intermediate layer 13 can function as an adhesive layer. The intermediate layer 13 can include any suitable material. The intermediate layer 13 can be, for example, an oxide layer (e.g., a silicon dioxide (SiO₂) layer). One or more additional layers can be inserted between the intermediate layer 13 and the support substrate 10 to prevent or mitigate the unwanted electrical leakage on the surface of the support substrate 10. In some embodiments, one or more layers that include Poly-Si, Amorphas Si, Porous Si, SiN, and/or AlN can be disposed between the intermediate layer 13 and the support substrate 10.

The illustrated IDT electrode 14 can include a first layer 16 and a second layer 18. The IDT electrode 14 includes first bus bar 20, a second bus bar 22, a first set of fingers 24 that extends from the first bus bar 20, and a second set of fingers 26 that extends from the second bus bar 22. The first set of fingers 24 includes a first finger 24a and the second set of fingers 26 includes a second finger 26a. Each of the first set of fingers 24 and each of the second set of fingers 26 can be identical or generally similar to one another. In the SAW device 1, the IDT electrode 14 includes separate IDT layers (e.g., the first layer 16 and the second layer 18) that impact acoustic properties and electrical properties. Accordingly, in some embodiments, electrical properties, such as insertion loss, can be improved by adjusting one of the IDT layers without significantly impacting acoustic properties.

The first layer 16 of the IDT electrode 14 can be referred to as a lower electrode layer. The first layer 16 of the IDT electrode 14 is positioned between the second layer 18 of the IDT electrode 14 and the piezoelectric layer 12. As illustrated, the first layer 16 of the IDT electrode 14 can have a first side in physical contact with the piezoelectric layer 12 and a second side in physical contact with the second layer 18 of the IDT electrode 14. The second layer 18 of the IDT electrode 14 can be referred to as an upper electrode layer. The second layer 18 of the IDT electrode 14 can be disposed over the first layer 16 of the IDT electrode 14. As illustrated, the second layer 18 of the IDT electrode 14 can have a first side in physical contact with the first layer 16 of the IDT electrode 14. In some other embodiments, the first layer 16 and the second layer 18 can be switched.

The IDT electrode 14 can include any suitable material. For example, the first layer 16 can be tungsten (W) and the second layer 18 can be aluminum (Al) in certain embodiments. The IDT electrode 14 may include one or more other metals, such as copper (Cu), Magnesium (Mg), titanium (Ti), molybdenum (Mo), etc. The IDT electrode 14 may include alloys, such as AlMgCu, AlCu, etc. In some embodiments, a thickness of the first layer 16 can be in a range from 0.01L to 0.075L and a thickness of the second layer 18 can be in a range from 0.05L to 0.2L. For example, when the wavelength L is 4 μm, the thickness of the first layer 16 can be about 40 nm to 300 nm and the thickness of the second layer 18 can be about 200 nm to 800 nm. Although the IDT electrode 14 has a dual-layer structure in the illustrated embodiments, any suitable principles and advantages disclosed herein can be applied to single layer IDT electrodes or multi-layer IDT electrodes that include three or more IDT layers. The IDT electrode 14 can be formed with (e.g., formed on or at least partially in) the piezoelectric layer 12. The piezoelectric layer 12 and the IDT electrode 14 can be provided in any suitable manner. For example, the piezoelectric layer 12 and the IDT electrode 14 can be provided in sequence. When the interdigital transducer electrode is provided at least partially in the piezoelectric layer 12, the piezoelectric layer 12 can be partially etched and/or provided in a plurality of steps.

The SAW device 1 can include a first gap region GR1 between the first set of fingers 24 and the second bus bar 22, a second gap region GR2 between the second set of fingers 26 and the first bus bar 20, and an active region AR between the first and second gap regions GR1, GR2. In some embodiments, the IDT electrode 14 can include a first mini-bus bar 30 in the second gap region GR2 and a second mini-bus bar 32 in the first gap region GR1. The active region AR includes a center region CR, a first border region BR1 between the center region CR and the first gap region GR1, and a second border region BR2 between the center region CR and the second gap region GR2. The first and second border regions BR1, BR2 can be regions within 0.5L, 1L, or 1.5L of the first and second sets of fingers 24, 26 from respective edges of the first and second sets of fingers 24, 26 or from the respective first or second gap regions GR1, GR2. In some embodiments, the first and second border regions BR1, BR2 can have a length in a range between about 0.5L and about 1.5L or about 1L and about 1.5L.

The first and second sets of fingers 24, 26 of the IDT electrode 14 can include a multi-hammer head structure (e.g., a double hammer head structure 36) in the first border region BR1 and the second border region BR2. The double hammer head structure 36 can include a first portion 36a, a second portion 36b, and a third portion 36c. For example, the first portion 36a of the first finger 24a can be positioned between the first gap region GR1 and the second portion 36b, the second portion 36b can be positioned between the first portion and the third portion 36c, and the third portion 36c can be positioned between the second portion 36b and the center region CR. The double hammer head structure 36 can also be referred to as a three-step hammer head structure. The first portion 36a has a width w1, the second portion 36b has a width w2, and the third portion 36c has a width w3. The width w1 of the first portion 36a and the width w3 of the third portion 36c can be greater than the width w2 of the second portion 36b and a width w4 of the first and second sets of fingers 24, 26 in the center region CR. Therefore, the first portion 36a and the third portion 36c can have liner densities along a length direction that is greater than liner densities of the second portion 36b and the center region CR. The width w1 of the first portion 36a and the width w3 of the third portion 36c that are greater than the width w4 of the first and second sets of fingers 24, 26 in the center region CR can add mass in the first border region BR1 and the second border region BR2 thereby enabling mass loading effect to provide the piston mode. A difference between the width w2 and the widths w1, w3 can be referred to as a notch. The width w2 of the second portion 36b can be the same as, greater than, or less than the width w4 of the first and second sets of fingers 24, 26 in the center region CR. The width w4 of the first and second sets of fingers 24, 26 in the center region CR can be greater than a width w7 of the first and second sets of fingers 24, 26 in a gap region GR1, GR2 between the active region AR and the bus bar 20, 22.

The second set of fingers 26 located between the second mini-bus bar 32 and the active region AR have a width w6. A width of the first set of fingers 24 located between the first mini-bus bar 30 and the active region AR can be the same as or similar to the width w6. The second set of fingers 26 located between the second mini-bus bar 32 and the second bus bar 22 have a width 7. A width of the first set of fingers 24 located between the first mini-bus bar 30 and the first bus bar 20 can be the same as or similar to the width w7. The widths w6, w7 can be the same as or narrower than the width w4.

In some embodiments, the width w1 of the first portion 36a can be in a range between 0.2L and 0.4L, or 0.25L and 0.35L. In some embodiments, the width w2 of the second portion 36b can be in a range between 0.11L and 0.31L, or 0.16L and 0.26L. In some embodiments, the width w3 of the third portion 36c can be in a range between 0.2L and 0.4L, or 0.25L and 0.35L. In some embodiments, the width w4 of the first and second sets of fingers 24, 26 in the center region CR can be in a range between 0.11L and 0.31L, or 0.16L and 0.26L. In some embodiments, the width w1 of the first portion 36a and the width w3 of the third portion 36c can be 10% to 50% greater, or 15% to 40% greater than the width w2 of the second portion 36b or the width w4 of the first and second sets of fingers 24, 26 in the center region CR.

The first portion 36a has a length l1, the second portion 36b has a length l2, and the third portion 36c has a length l3. The double hammer head structure 36 has a length l4 (l1+l2+l3). In some embodiments, the length l2 of the second portion 36b can be relatively small. The length l2 of the second portion 36b can be shorter than a total length of the first portion 36a and the third portion 36c (l1+l3). In some embodiments, the length l2 of the second portion 36b can be in a range between 10% and 45%, 10% and 35%, 10% and 25%, 15% and 45%, or 15% and 35% of the length l4 of the double hammer head structure 36. In some embodiments, the length l2 of the second portion 36b can be in a range between 0.01L and 0.7L, 0.1L and 0.7L, 0.1L and 0.5L, or 0.2L and 0.5L.

In some embodiments, the length l1 of the first portion 36a and the length l3 of the third portion 36c can be different. In some other embodiments, the length l1 of the first portion 36a and the length l3 of the third portion 36c can be the same. The length l4 of the double hammer head structure 36 can be in a range between 0.1L and 1.5L, 0.3L and 1.5L, 0.5L and 1.5L, 0.1L and 1L, or 0.5L and 1L.

The first portion 36a of the double hammer head structure 36 can be spaced from the second mini-bus bar 32 by a length l5. The second mini-bus bar 32 can have a length l6. The second mini-bus bar 32 can be spaced from the second bus bar 22. The first portion 36a of the double hammer head structure 36 can be spaced from the second bus bar 22 by a length l8. In some embodiments, the length l5 can be in a range between 0.05L and 0.25L, or 0.1L and 0.2L. In some embodiments, the length l6 can be in a range between 0.05L and 0.25L, or 0.1L and 0.2L. In some embodiments, the length l7 can be in a range between 0.2L and 0.8L, or 0.3L and 0.7L. In some embodiments, the length l8 can be in a range between 0.3L and 1.3L, or 0.7L and 0.9L.

In general, the width of the IDT fingers compared to the width of the spacing between the IDT fingers sets a duty factor (DF). Specifically, the duty factor is defined as the fraction of the IDT width spanned by the width of the IDT fingers (in the direction of propagation of the main surface acoustic wave to be generated). Increasing the width of the IDT fingers, while maintaining the position of the center of each IDT finger, increases the duty factor. In some embodiments, the duty factor (DF) of the first portion 36a can be in a range between 50 and 70, the DF of the second portion 36b can be in a range between 33 and 53, and the DF of the third portion 36c can be in a range between 50 and 70.

FIG. 1D is a schematic top plan view of a portion of a SAW device 2 that has a single hammer head structure 40. Unlike the multi-hammer head structure (e.g., a double hammer head structure 36) of the SAW device 1, the single hammer head structure 40 does not include portions that have different widths. The single hammer head structure 40 has a length l9 and a width w5.

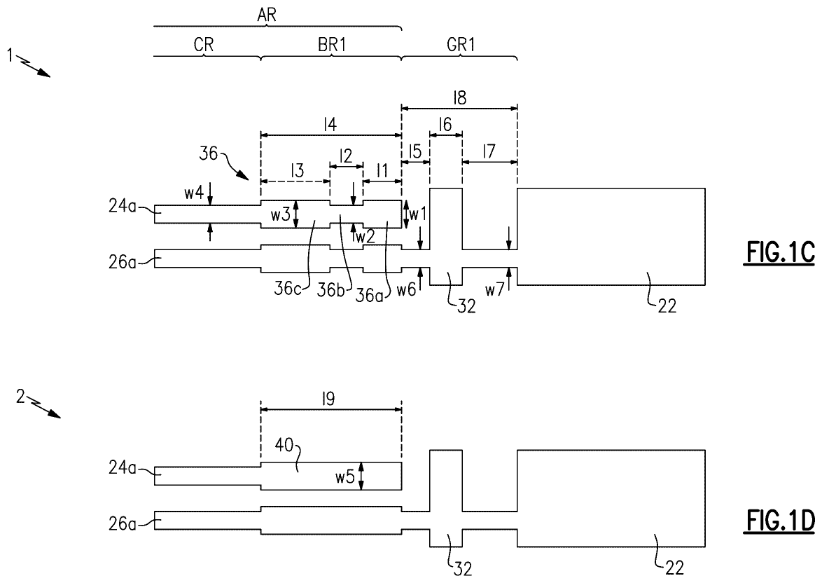

FIGS. 2A-2C are graphs showing simulation results of the SAW device 1 and the SAW device 2. In the simulations, the width w1 of the first portion 36a is set to 0.3L, the width w2 of the second portion 36b is set to 0.21L, the width w3 of the third portion 36c is set to 0.3L, the width w4 of the fingers 24, 26 in the center region CR is set to 0.21L, the length l1 of the first portion 36a is set to 0.25L, the length l2 of the second portion 36b is set to 0.25L, the length l3 of the third portion 36c is set to 0.5L, the length l5 is set to 0.15L, the length l6 is set to 0.15L, the length l7 is set to 0.5L, the width w5 of the single hammer head structure 40 is set to 0.3L, and the length l9 of the single hammer head structure 40 is set to 1L.

The simulation results of FIGS. 2A-2C indicate that the double hammer head structure 36 can provide an improved wave trapping ability as compared to the single hammer head structure 40. The double hammer head structure 36 can enable the SAW device 1 to reduce transverse leakage and improve the quality factor Q. In some embodiments, the notch or the second portion 36b that has the width w2 that is narrower than the first and third portions 36a, 36c can be utilized in other SAW devices. For example, FIGS. 3A-3D includes a narrow portion or the notch in the border regions BR1, BR2.

FIG. 3A is a schematic top plan view of a SAW device 3 according to an embodiment. FIG. 3B is a schematic cross-sectional side view of the SAW device 3 taken along a section of the SAW device 3. FIG. 3C is a schematic cross-sectional side view of the SAW device 3 taken along another section of the SAW device 3. FIG. 3D is a schematic top plan view of a portion of the SAW device 3 of FIGS. 3A-3C. Unless otherwise noted, the components of the acoustic wave device 3 shown in FIGS. 3A-3D may be structurally and/or functionally the same as or generally similar to like components disclosed herein. The SAW device 3 can include a support substrate 10, a piezoelectric layer 12, an intermediate layer 13 between the support substrate 10 and the piezoelectric layer 12, and an interdigital transducer (IDT) electrode 14 in electrical communication with the piezoelectric layer. In the illustrated embodiment, the IDT electrode 14 is formed over the piezoelectric layer 12.

A first set of fingers 24 and a second set of fingers 26 can include a first portion 50a, a second portion 50b, and a third portion 50c. In some embodiments, widths of the first portion 50a and the third portion 50c can be the same as a width w4 of the first and second sets of fingers 24, 26 in the center region CR. The second portion 50b has a width w8 that is narrower than the width w4. The second portion 50b can also be referred to as a narrow portion. A difference in the widths of the first portion 50a and the second portion 50b or the second portion 50b and the third portion 50c can define a notch 50d. In some embodiments, the width w4 of the first and second sets of fingers 24, 26 in the center region CR (e.g., the width of the first portion 50a and the third portion 50c in the illustrated embodiment) can be 10% to 50% greater, or 15% to 40% greater than the width w8 of the second portion 50b.

The first portion 50a has a length l1, the second portion 50b has a length l2, and the third portion 50c has a length l3. In some embodiments, the length l2 of the second portion 50b can be relatively small. The length l2 of the second portion 50b can be shorter than a total length of the first portion 50a and the third portion 36c (l1+l3). In some embodiments, the length l2 of the second portion 50b can be in a range between 10% and 45%, 10% and 35%, 10% and 25%, 15% and 45%, or 15% and 35% of a total length of the first to third portions 50a, 50, 50c (l1+l2+l3). In some embodiments, the length l1 of the first portion 50a and the length l3 of the third portion 50c can be different. In some other embodiments, the length l1 of the first portion 50a and the length l3 of the third portion 50c can be the same. The total length of the first to third portions 50a, 50, 50c (l1+l2+l3) can be in a range between 0.1L and 1.5L, 0.3L and 1.5L, 0.5L and 1.5L, 0.1L and 1L, or 0.5L and 1L.

The piezoelectric layer 12 can include a trench 52 in the first and second border regions BR1, BR2. In some embodiments, the trench 52 can have a trench depth in a range of 5% to 75% of the thickness of the piezoelectric layer 12. For example, the trench depth of the trench 52 can be in a range between 2% and 10%, 2% and 7%, or 5% and 10% of the thickness of the piezoelectric layer 12.

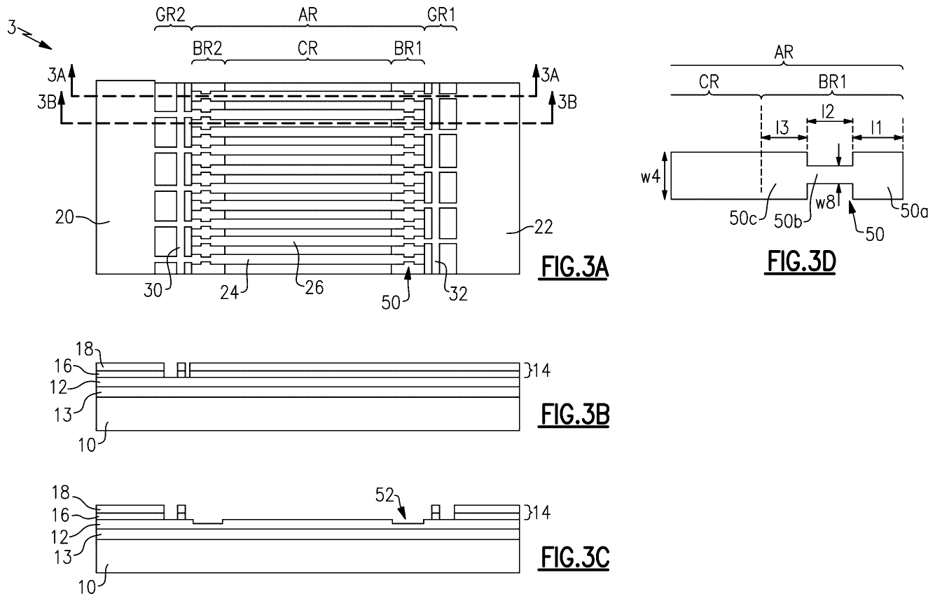

FIGS. 4A-4C are graphs showing simulation results of the SAW device 3. The simulations were conducted for the SAW device 3 with the notch 50d and the trench 52, and without the notch 50d (w3=w8) and the trench 52 (the trench depth=0). The simulation results indicate that the combination of the notch 50d and the trench 52 can provide an improved wave trapping ability as compared to a similar SAW device without the notch 50d and the trench 52. The combination of the notch 50d and the trench 52 can enable the SAW device 1 to reduce transverse leakage and improve the quality factor Q.

FIG. 5A is a schematic top plan view of a surface acoustic wave (SAW) device 4 according to an embodiment. FIG. 5B is a schematic cross-sectional side view of the SAW device 4 of FIG. 5A. FIG. 5C is a schematic cross-sectional side view of a portion of the SAW device 4 of FIG. 5A. Unless otherwise noted, the components of the acoustic wave device 4 shown in FIGS. 5A-5C may be structurally and/or functionally the same as or generally similar to like components disclosed herein. Although the illustrated SAW device 4 illustrates an interdigital transducer (IDT) electrode 14 that includes only one layer, the IDT electrode 14 of the SAW device 4 may include two or more layers, in some embodiments.

First and second sets of fingers 24, 26 of the IDT electrode 14 can include a multi-thickness step structure 56 in the first border region BR1 and the second border region BR2. The first set of fingers 24 and the second set of fingers 26 can include a first portion 56a, a second portion 56b, and a third portion 56c in the first and second border regions BR1, BR2. The first portion 56a has a thickness t1, the second portion 56b has a thickness t2, and the third portion 56c has a thickness t3. The thickness t1 of the first portion 56a and the thickness t3 of the third portion 56c can be greater than the thickness t2 of the second portion 56b and a thickness t4 of the first and second sets of fingers 24, 26 in the center region CR. Therefore, the first portion 56a and the third portion 56c can have liner densities along a length direction that is greater than liner densities of the second portion 56b and the center region CR. The thickness t1 of the first portion 56a and the thickness t3 of the third portion 56c that are greater than the thickness t4 of the first and second sets of fingers 24, 26 in the center region CR can add mass in the first border region BR1 and the second border region BR2 thereby enabling mass loading effect to provide the piston mode. The second portion 56b that has the thickness t2 that is thinner than the thicknesses t1, t2 of the first and second portions 56a, 56c, can function in a similar manner as and provide the benefits of the second portion 36b of the double hammer head structure 36 shown in FIGS. 1A-1C. In some embodiments, the thickness t1 of the first portion 56a and the thickness t3 of the third portion 56c can be 10% to 40% greater, or 15% to 35% greater than the thickness t2 of the second portion 56b or the thickness t4 of the first and second sets of fingers 24, 26 in the center region CR. The thickness t4 of the first and second sets of fingers 24, 26 in the center region CR can be greater than a thickness of the first and second sets of fingers 24, 26 in the gap region Gra, GR2 between the active region AR and the bus bar 20, 22.

The first portion 56a has a length l1, the second portion 56b has a length l2, and the third portion 56c has a length l3. In some embodiments, the length l2 of the second portion 56b can be relatively small. The length l2 of the second portion 56b can be shorter than a total length of the first portion 56a and the third portion 56c (l1+l3). In some embodiments, the length l2 of the second portion 56b can be in a range between 5% and 45%, 5% and 35%, 5% and 25%, 15% and 45%, or 15% and 35% of a total length of the first to third portions 56a, 56b, 56c (l1+l2+l3). In some embodiments, the length l1 of the first portion 56a and the length l3 of the third portion 56c can be different. In some other embodiments, the length l1 of the first portion 56a and the length l3 of the third portion 56c can be the same. The total length of the first to third portions 56a, 56b, 56c (l1+l2+l3) can be in a range between 0.1L and 1.5L, 0.3L and 1.5L, 0.5L and 1.5L, 0.1L and 1L, or 0.5L and 1L.

Any suitable principles and advantages disclosed herein can be combined with one another. The trench in the piezoelectric layer disclosed with respect to FIGS. 3A-3C can be implemented with any suitable piston mode structure, such as a multi-hammer head structure or a multi-thickness step structure. Also, in some embodiments, the multi-hammer head structure and the multi-thickness step structure can be implemented in a single SAW device such that there are multiple liner densities in the border region. In some embodiments, multiple liner densities in the border region can include different materials. The liner density can be the mass per length.

For example, a finger of an interdigital transducer electrode can have a border region with a first portion, a second portion between the first portion and a center region, and a third portion between the second portion and the center regio. The second portion can have a liner density along the length direction of the finger that is less than liner densities of the first and third portions. In some embodiments, the liner density of the first and/or the liner density of the third portion can be in a range between 10% and 40%, 10% and 30%, 10% and 20%, 20% and 40%, or 20% and 30%, greater than the liner density of the second portion.

An acoustic wave device (e.g., a SAW device) including any suitable combination of features disclosed herein can be included in a filter arranged to filter a radio frequency signal in a fifth generation (5G) New Radio (NR) operating band within Frequency Range 1 (FR1). A filter arranged to filter a radio frequency signal in a 5G NR operating band can include one or more conductive structures disclosed herein. FR1 can be from 410 MHz to 7.125 GHz, for example, as specified in a current 5G NR specification. One or more acoustic wave devices in accordance with any suitable principles and advantages disclosed herein can be included in a filter arranged to filter a radio frequency signal in a 4G LTE operating band and/or in a filter having a passband that includes a 4G LTE operating band and a 5G NR operating band.

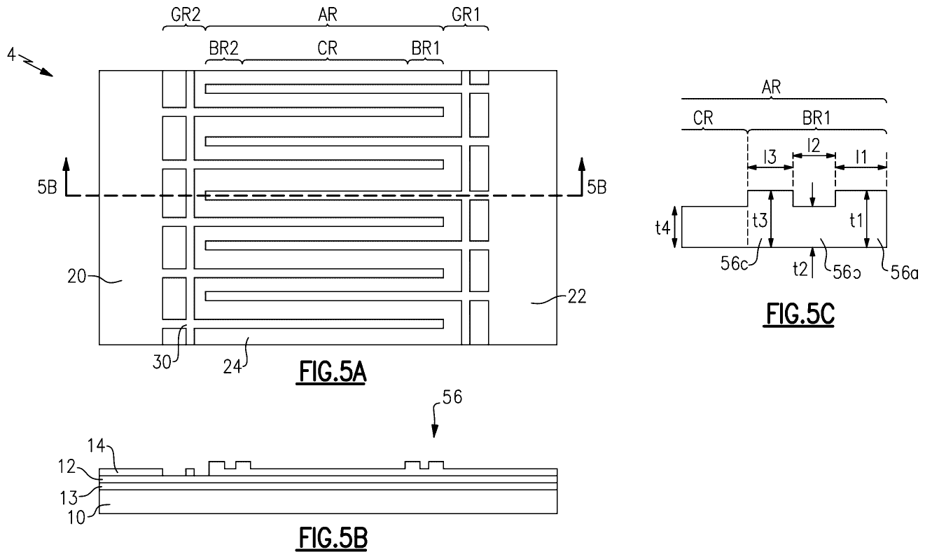

FIG. 6A is a schematic diagram of an example transmit filter 100 that includes surface acoustic wave devices according to an embodiment. The transmit filter 100 can be a band pass filter. The illustrated transmit filter 100 is arranged to filter a radio frequency signal received at a transmit port TX and provide a filtered output signal to an antenna port ANT. Some or all of the SAW resonators TS1 to TS7 and/or TP1 to TP5 can be SAW devices in accordance with any suitable principles and advantages disclosed herein. For instance, one or more of the SAW resonators of the transmit filter 100 can be coupled by way of a conductive structure disclosed herein. Any suitable number of series SAW resonators and shunt SAW resonators can be included in a transmit filter 100.

FIG. 6B is a schematic diagram of a receive filter 105 that includes surface acoustic wave devices according to an embodiment. The receive filter 105 can be a band pass filter. The illustrated receive filter 105 is arranged to filter a radio frequency signal received at an antenna port ANT and provide a filtered output signal to a receive port RX. Some or all of the SAW resonators RS1 to RS8 and/or RP1 to RP6 can be SAW resonators in accordance with any suitable principles and advantages disclosed herein. Any suitable number of series SAW resonators and shunt SAW resonators can be included in a receive filter 105.

Although FIGS. 6A and 6B illustrate example ladder filter topologies, any suitable filter topology can include a conductive structure in accordance with any suitable principles and advantages disclosed herein. Example filter topologies include ladder topology, a lattice topology, a hybrid ladder and lattice topology, a multi-mode SAW filter, a multi-mode SAW filter combined with one or more other SAW resonators, and the like.

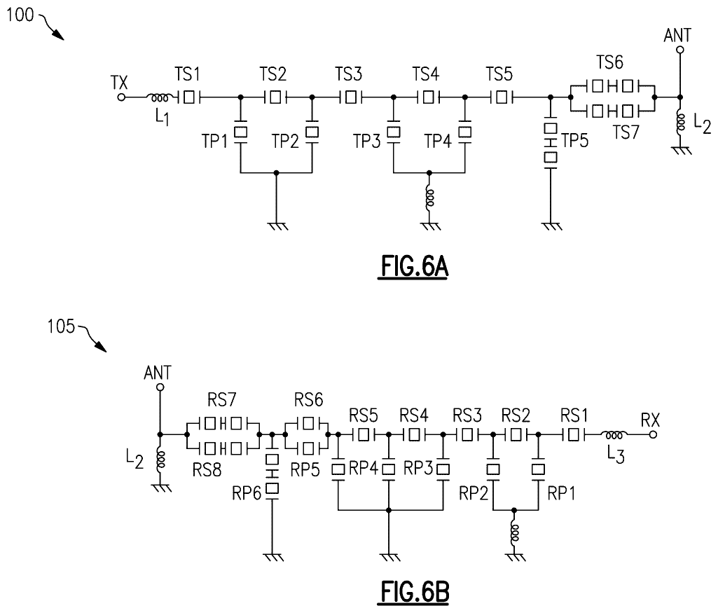

FIG. 7 is a schematic diagram of a radio frequency module 175 that includes a surface acoustic wave component 176. The illustrated radio frequency module 175 includes the SAW component 176 and other circuitry 177. The SAW component 176 can include one or more SAW resonators with any suitable combination of features of the SAW resonators disclosed herein. The SAW component 176 can include a SAW die that includes SAW resonators.

The SAW component 176 shown in FIG. 7 includes a filter 178 and terminals 179A and 179B. The filter 178 includes SAW resonators. One or more of the SAW resonators can be implemented in accordance with any suitable principles and advantages of any surface acoustic wave device disclosed herein. The terminals 179A and 178B can serve, for example, as an input contact and an output contact. The SAW component 176 and the other circuitry 177 are on a common packaging substrate 180 in FIG. 7. The package substrate 180 can be a laminate substrate. The terminals 179A and 179B can be electrically connected to contacts 181A and 181B, respectively, on the packaging substrate 180 by way of electrical connectors 182A and 182B, respectively. The electrical connectors 182A and 182B can be bumps or wire bonds, for example. The other circuitry 177 can include any suitable additional circuitry. For example, the other circuitry can include one or more one or more power amplifiers, one or more radio frequency switches, one or more additional filters, one or more low noise amplifiers, the like, or any suitable combination thereof. The radio frequency module 175 can include one or more packaging structures to, for example, provide protection and/or facilitate easier handling of the radio frequency module 175. Such a packaging structure can include an overmold structure formed over the packaging substrate 180. The overmold structure can encapsulate some or all of the components of the radio frequency module 175.

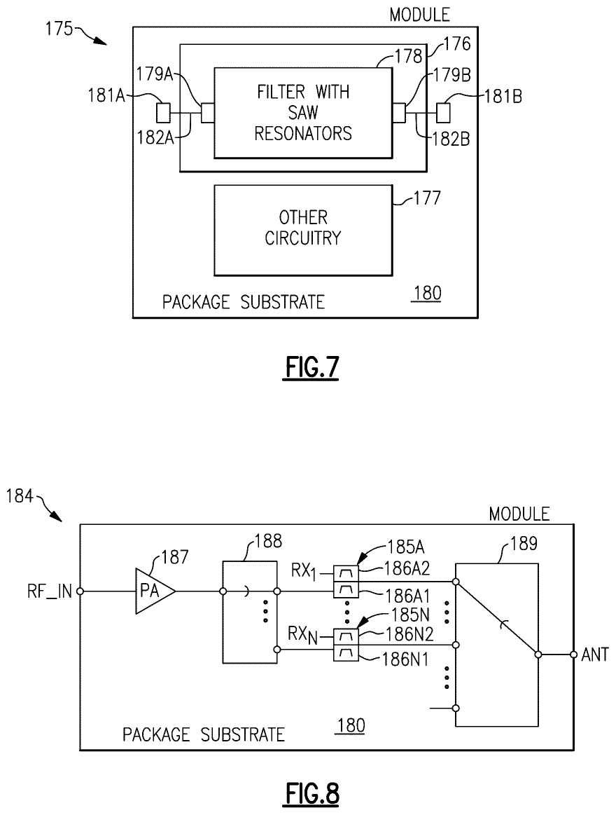

FIG. 8 is a schematic diagram of a radio frequency module 184 that includes a surface acoustic wave resonator according to an embodiment. As illustrated, the radio frequency module 184 includes duplexers 185A to 185N that include respective transmit filters 186A1 to 186N1 and respective receive filters 186A2 to 186N2, a power amplifier 187, a select switch 188, and an antenna switch 189. In some instances, the module 184 can include one or more low noise amplifiers configured to receive a signal from one or more receive filters of the receive filters 186A2 to 186N2. The radio frequency module 184 can include a package that encloses the illustrated elements. The illustrated elements can be disposed on a common packaging substrate 180. The packaging substrate can be a laminate substrate, for example.

The duplexers 185A to 185N can each include two acoustic wave filters coupled to a common node. The two acoustic wave filters can be a transmit filter and a receive filter. As illustrated, the transmit filter and the receive filter can each be band pass filters arranged to filter a radio frequency signal. One or more of the transmit filters 186A1 to 186N1 can include one or more SAW resonators in accordance with any suitable principles and advantages disclosed herein. Similarly, one or more of the receive filters 186A2 to 186N2 can include one or more SAW resonators in accordance with any suitable principles and advantages disclosed herein. Although FIG. 8 illustrates duplexers, any suitable principles and advantages disclosed herein can be implemented in other multiplexers (e.g., quadplexers, hexaplexers, octoplexers, etc.) and/or in switch-plexers and/or to standalone filters.

The power amplifier 187 can amplify a radio frequency signal. The illustrated switch 188 is a multi-throw radio frequency switch. The switch 188 can electrically couple an output of the power amplifier 187 to a selected transmit filter of the transmit filters 186A1 to 186N1. In some instances, the switch 188 can electrically connect the output of the power amplifier 187 to more than one of the transmit filters 186A1 to 186N1. The antenna switch 189 can selectively couple a signal from one or more of the duplexers 185A to 185N to an antenna port ANT. The duplexers 185A to 185N can be associated with different frequency bands and/or different modes of operation (e.g., different power modes, different signaling modes, etc.).

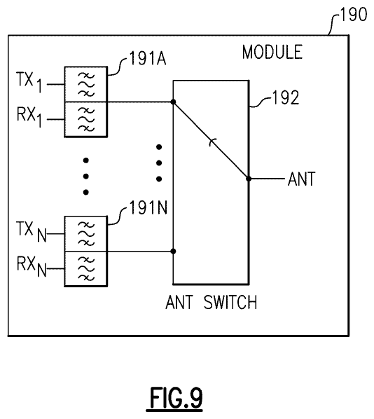

FIG. 9 is a schematic block diagram of a module 190 that includes duplexers 191A to 191N and an antenna switch 192. One or more filters of the duplexers 191A to 191N can include any suitable number of surface acoustic wave resonators in accordance with any suitable principles and advantages discussed herein. Any suitable number of duplexers 191A to 191N can be implemented. The antenna switch 192 can have a number of throws corresponding to the number of duplexers 191A to 191N. The antenna switch 192 can electrically couple a selected duplexer to an antenna port of the module 190.

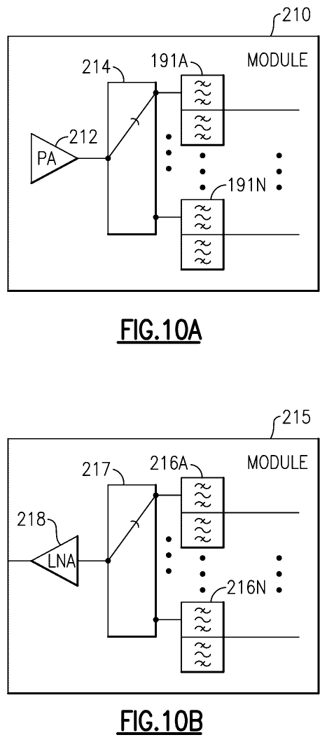

FIG. 10A is a schematic block diagram of a module 210 that includes a power amplifier 212, a radio frequency switch 214, and duplexers 191A to 191N in accordance with one or more embodiments. The power amplifier 212 can amplify a radio frequency signal. The radio frequency switch 214 can be a multi-throw radio frequency switch. The radio frequency switch 214 can electrically couple an output of the power amplifier 212 to a selected transmit filter of the duplexers 191A to 191N. One or more filters of the duplexers 191A to 191N can include any suitable number of surface acoustic wave resonators in accordance with any suitable principles and advantages discussed herein. Any suitable number of duplexers 191A to 191N can be implemented.

FIG. 10B is a schematic block diagram of a module 215 that includes filters 216A to 216N, a radio frequency switch 217, and a low noise amplifier 218 according to an embodiment. One or more filters of the filters 216A to 216N can include any suitable number of acoustic wave resonators in accordance with any suitable principles and advantages disclosed herein. Any suitable number of filters 216A to 216N can be implemented. The illustrated filters 216A to 216N are receive filters. In some embodiments, one or more of the filters 216A to 216N can be included in a multiplexer that also includes a transmit filter. The radio frequency switch 217 can be a multi-throw radio frequency switch. The radio frequency switch 217 can electrically couple an output of a selected filter of filters 216A to 216N to the low noise amplifier 218. In some embodiments, a plurality of low noise amplifiers can be implemented. The module 215 can include diversity receive features in certain applications.

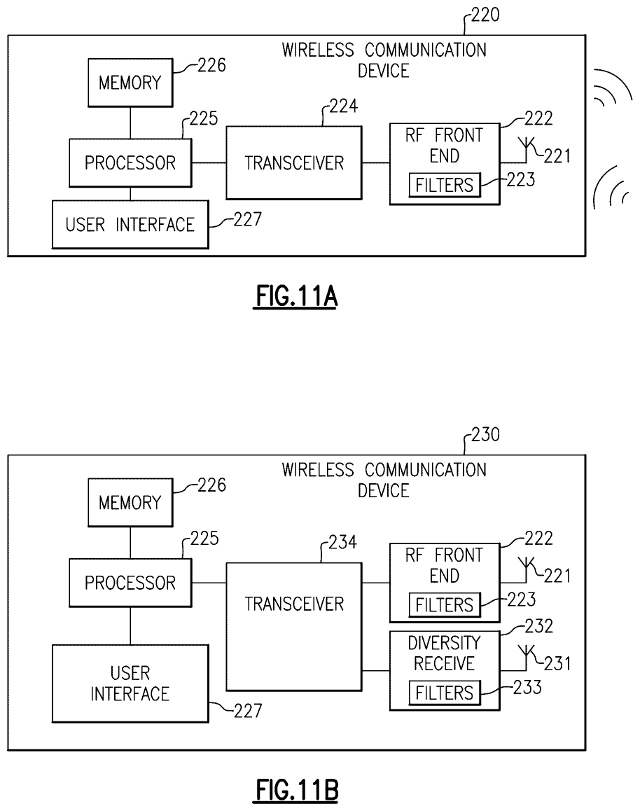

FIG. 11A is a schematic diagram of a wireless communication device 220 that includes filters 223 in a radio frequency front end 222 according to an embodiment. The filters 223 can include one or more SAW resonators in accordance with any suitable principles and advantages discussed herein. The wireless communication device 220 can be any suitable wireless communication device. For instance, a wireless communication device 220 can be a mobile phone, such as a smart phone. As illustrated, the wireless communication device 220 includes an antenna 221, an RF front end 222, a transceiver 224, a processor 225, a memory 226, and a user interface 227. The antenna 221 can transmit/receive RF signals provided by the RF front end 222. Such RF signals can include carrier aggregation signals. Although not illustrated, the wireless communication device 220 can include a microphone and a speaker in certain applications.

The RF front end 222 can include one or more power amplifiers, one or more low noise amplifiers, one or more RF switches, one or more receive filters, one or more transmit filters, one or more duplex filters, one or more multiplexers, one or more frequency multiplexing circuits, the like, or any suitable combination thereof. The RF front end 222 can transmit and receive RF signals associated with any suitable communication standards. The filters 223 can include SAW resonators of a SAW component that includes any suitable combination of features discussed with reference to any embodiments discussed above.

The transceiver 224 can provide RF signals to the RF front end 222 for amplification and/or other processing. The transceiver 224 can also process an RF signal provided by a low noise amplifier of the RF front end 222. The transceiver 224 is in communication with the processor 225. The processor 225 can be a baseband processor. The processor 225 can provide any suitable base band processing functions for the wireless communication device 220. The memory 226 can be accessed by the processor 225. The memory 226 can store any suitable data for the wireless communication device 220. The user interface 227 can be any suitable user interface, such as a display with touch screen capabilities.

FIG. 11B is a schematic diagram of a wireless communication device 230 that includes filters 223 in a radio frequency front end 222 and a second filter 233 in a diversity receive module 232. The wireless communication device 230 is like the wireless communication device 220 of FIG. 11A, except that the wireless communication device 230 also includes diversity receive features. As illustrated in FIG. 11B, the wireless communication device 230 includes a diversity antenna 231, a diversity module 232 configured to process signals received by the diversity antenna 231 and including filters 233, and a transceiver 234 in communication with both the radio frequency front end 222 and the diversity receive module 232. The filters 233 can include one or more SAW resonators that include any suitable combination of features discussed with reference to any embodiments discussed above.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a frequency range from about 30 kHz to 300 GHZ, such as in a frequency range from about 450 MHz to 8.5 GHZ. Acoustic wave resonators and/or filters disclosed herein can filter RF signals at frequencies up to and including millimeter wave frequencies.

Aspects of this disclosure can be implemented in various electronic devices. Examples of the electronic devices can include, but are not limited to, consumer electronic products, parts of the consumer electronic products such as packaged radio frequency modules and/or packaged filter components, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. As used herein, the term “approximately” intends that the modified characteristic need not be absolute, but is close enough so as to achieve the advantages of the characteristic. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A multilayer piezoelectric substrate acoustic wave device including an active region having a center region and a border region, the acoustic wave device comprising:
a support substrate;
a piezoelectric layer over the support substrate; and
an interdigital transducer electrode in electrical communication with the piezoelectric layer, the interdigital transducer electrode including a bus bar and a finger extending from the bus bar, the finger in the border region having a first portion, a second portion between the center region and the first portion, and a third portion between the center region and the second portion, a liner density of the first portion and a liner density of the third portion being greater than a liner density of the second portion and a liner density of the finger in the center region.

2. The acoustic wave device of claim 1 wherein the interdigital transducer electrode includes a first layer having a first material and a second layer having a second material different from the first material.

3. The acoustic wave device of claim 1 wherein the interdigital transducer electrode includes a mini-bus bar between the bus bar and the active region.

4. The acoustic wave device of claim 1 wherein the liner density of the first portion is at least 10% greater than the liner density of the second portion.

5. The acoustic wave device of claim 4 wherein the liner density of the first portion is 10% to 40% greater than the liner density of the second portion.

6. The acoustic wave device of claim 4 wherein the liner density of the first portion is 10% to 30% greater than the liner density of the second portion.

7. The acoustic wave device of claim 1 wherein the densities of the first portion and the third portion are different.

8. The acoustic wave device of claim 1 wherein the border region is a region within 1.5L from an edge of the finger farthest from the bus bar, where a surface acoustic wave generated by the acoustic wave device has a wavelength L.

9. The acoustic wave device of claim 8 wherein the second portion has a length that extends between the first portion and the third portion in a range of 0.1L and 0.7L.

10. The acoustic wave device of claim 8 wherein a width of the finger in the center region is greater than a fifth width of the finger in a gap region between the active region and the bus bar.

11. A method of forming a multilayer piezoelectric substrate acoustic wave device including an active region having a center region and a border region, the method comprising:
providing a support substrate;
providing a piezoelectric layer over the support substrate; and
providing an interdigital transducer electrode in electrical communication with the piezoelectric layer, the interdigital transducer electrode including a bus bar and a finger extending from the bus bar, the finger in the border region having a first portion, a second portion between the center region and the first portion, and a third portion between the center region and the second portion, the first portion and the third portion having liner densities greater than liner densities of the second portion and the finger in the center region.

12. The method of claim 11 wherein the interdigital transducer electrode includes a first layer having a first material and a second layer having a second material different from the first material.

13. The method of claim 11 wherein providing the interdigital transducer electrode includes forming a mini-bus bar between the bus bar and the active region.

14. The method of claim 11 wherein the liner density of the first portion is at least 10% greater than the liner density of the second portion.

15. The method of claim 14 wherein the liner density of the first portion is 10% to 40% greater than the liner density of the second portion.

16. The method of claim 14 wherein the liner density of the first portion is 10% to 30% greater than the liner density of the second portion.

17. The method of claim 11 wherein the densities of the first portion and the third portion are different.

18. The method of claim 11 wherein the border region is a region within 1.5L from an edge of the finger farthest from the bus bar, where a surface acoustic wave generated by the acoustic wave device has a wavelength L.

19. The method of claim 18 wherein the second portion has a length that extends between the first portion and the third portion in a range of 0.1L and 0.7L.

20. A multilayer piezoelectric substrate acoustic wave device including an active region having a center region and a border region, the acoustic wave device comprising:
a support substrate;
a piezoelectric layer over the support substrate, the piezoelectric layer having a trench in the border region; and
an interdigital transducer electrode in electrical communication with the piezoelectric layer, the interdigital transducer electrode including a bus bar and a finger extending from the bus bar, the finger in the border region having a first portion, a second portion between the center region and the first portion, and a third portion between the center region and the second portion, the first portion and the third portion having liner densities greater than liner density of the second portion.
